(19) United States
(12) Patent Application Publication
(10) Pub. No.: US 2023/0168567 A1
(43) Pub. Date: Jun. 1, 2023

(54) Security Device

(71) Applicant: Essence Security International (E.S.I.) Ltd., Herzlia Pituach (IL)

(72) Inventors: Elly GAZAL, Tel Mond (IL); Eran COHEN, Tel-Aviv (IL)

(21) Appl. No.: 17/921,628

(22) PCT Filed: Apr. 29, 2021
(86) PCT No.: PCT/IL2021/050495

§ 371 Date: Oct. 26, 2022

(30) Foreign Application Priority Data
Apr. 29, 2020 (GB) 2006312.9

(51) Int. Cl. G03B 17/56; G03B 17/02; H04N 23/51

(52) U.S. Cl. CPC G03B 17/561; G03B 17/02; H04N 23/51

(57) ABSTRACT

A security device comprises a housing assembly comprising a mounting bracket and a main housing detachably mountable to the mounting bracket. The housing assembly has a closed configuration that can be at least partially opened using a first mechanism. When the housing assembly is at least partially opened, a second mechanism is accessible to be manipulated to enable movement of the main housing with respect to the mounting bracket. In the closed configuration the second mechanism prevents movement of the main housing with respect to the mounting bracket and is inaccessible to thereby prevent said manipulation. A method of retaining a main housing of a security device on a mounting bracket when inserting a further housing component into engagement with the main housing is also disclosed.

### TECHNICAL FIELD

The present invention relates to a security device having a main housing and a mounting bracket and a method involving the security device. In some embodiments, the invention more specifically relates to security devices having a camera and/or a motion detector. The method may relate more specifically to enabling movement of the main housing with respect to the mounting bracket and/or to retaining the main housing on the mounting bracket when inserting a further housing component, such as a power supply housing, into the main housing.

### BACKGROUND

Security devices, such as those used in securing premises, typically comprise a main housing in which a camera or other sensor is provided along with associated control and communication components. The main housing is generally coupled to a power supply housing for supplying power to the camera and other components in the main housing. A mounting bracket is employed to attach the main housing to a support during use.

In some security devices, the power supply housing is removable from the main housing to facilitate battery replacement. In a wall-mounted security device, the power supply housing may be removable from a lower end of the main housing.

Furthermore, for some of such security devices, the mounting of the security device may require a main housing to be slidably engaged with the mounting bracket. For a wall-mounted device, this may require the main housing to be slid from above into engagement with the mounting bracket wherein, once engaged, friction and/or a ledge on at least one of the components may prevent further downward movement, for example, due to gravity.

Such a mounting arrangement may serve to adequately hold the components during normal operation of the security device. However, there may be challenges in relation to mounting the main housing to, or dismounting the main housing from, the mounting bracket.

It is therefore an aim of embodiments of the invention to at least ameliorate one or more of the above or other challenges or shortcomings of the prior art and/or to provide a useful alternative security device having a main housing and a mounting bracket, and/or alternative methods related to such a security device.

### SUMMARY

In general, some embodiments of the invention provide a security device having a closed configuration in which an internal mechanism is arranged to prevent movement of the main housing with respect to the mounting bracket. In the closed position, the internal mechanism is inaccessible. For example, a human-held tool and/or a person’s hand or part thereof (e.g. a finger in some embodiments) cannot access the internal mechanism. However, the internal mechanism is accessible when the housing assembly is in an at least partially open configuration to allow selective movement of the main housing. Movement of a housing component, such as a power supply housing, may place the device in the at least partially open configuration.

In a first aspect of the present invention, there is provided a security device comprising:
a housing assembly comprising a mounting bracket and a main housing detachably mountable to the mounting bracket;
wherein the housing assembly has a closed configuration that can be at least partially opened using a first mechanism;
wherein, when the housing assembly is at least partially opened, a second mechanism is accessible to be manipulated to enable movement of the main housing with respect to the mounting bracket;
wherein in the closed configuration the second mechanism prevents movement of the main housing with respect to the mounting bracket and is inaccessible to thereby prevent said manipulation;
wherein the housing assembly comprises a further housing component and wherein, in the closed configuration, the further housing component is in engagement with the main housing so as to make the second mechanism inaccessible; and
wherein the further housing component comprises a power supply housing for holding at least one power cell for supplying power to the security device.

Thus, certain embodiments of the invention provide a security device configured to retain a main housing on a mounting bracket until selectively moved (e.g. released therefrom). In addition, the selective movement of the main housing can only be achieved after the device is placed in an at least partially open configuration (e.g. after movement of a component such as a power supply housing) due to the inaccessibility of the second mechanism when the device is in the closed configuration. Accordingly, it is more difficult for an untrained person to remove the main housing from the mounting bracket, thus reducing the risk of removal by an unauthorized person. In some embodiments, removal of the power supply housing to enable access to the second mechanism in order to move (e.g. remove) the main housing, may trigger a notification that may be used to alert an operator that movement of at least a part of the device is in progress.

The closed configuration may be considered as an assembled configuration or a normal operating configuration (e.g. excluding a state of the device when in the process of being assembled, disassembled, repaired or under maintenance such as might be the case during replacement of a battery or the like).

The housing assembly may be at least partially opened when a portion of the device is moved, but not completely removed, in order to allow access to the second mechanism.

In some embodiments, the housing assembly may be fully opened (e.g. wherein a portion such a battery compartment of the device is completely removed) in order to allow access to the second mechanism. Thus, the second mechanism may be accessible to be manipulated only after complete removal of a part of the device.

In some embodiments the main housing may be moved with respect to the mounting bracket whilst still in engagement therewith (e.g. via a sliding movement). Additionally, or alternatively, the main housing may be moved with respect to the mounting bracket by separating the main housing from the mounting bracket.

It should be noted that components may be moveable in relation to one another (e.g. by sliding) whilst still being engaged. However, once in a locking engagement no further relative movement may be possible. The components may therefore be configured to be unlocked but still engaged. Disengagement may occur when the components are no longer in contact and the components are physically separated.

In the closed configuration, the second mechanism may be inaccessible if it cannot be accessed for manipulation by an operator using, for example, at least one of: a tool, a finger or other portion of a hand.

The first mechanism may be configured to move the further housing component with respect to the main housing to at least partially open the housing assembly and thereby make the second mechanism accessible.

The second mechanism may be configured such that movement of the main housing with respect to the mounting bracket is prevented at least during insertion of the further housing component into engagement with the main housing. For example, the second mechanism may prevent movement during one or more of: at a start of insertion (e.g. when the components first engage), at any time along a path of insertion; and at an end of insertion (e.g. when the further housing component is unable to be inserted further into engagement with the main housing).

The main housing may be slidably moveable with respect to the mounting bracket in a direction substantially aligned with a direction of insertion of the further housing component, when the second mechanism has been manipulated, and is restrained against said slidable movement by operation of the second mechanism at least during insertion of the further housing component into engagement with the main housing.

Removal of the power supply housing from the main housing may enable access to the second mechanism.The removal of the power supply housing to enable access to the second mechanism in order to remove the main housing may trigger a processor to generate a notification to indicate at least one of (i) that the housing assembly has been at least partially opened, and (ii) that the power supply housing has been accessed. The notification could comprise a local audio and/or visual notification at the device. In some embodiments the notification is a message transmitted to a control hub. The control hub may then decide what, if any, action to take as a result of the notification. For example, the device might only trigger an alarm if the system is armed. By contrast if the system is unarmed the device might trigger some other kind of action, e.g. it may send a notification to an offsite server, which may in turn notify an operator via an application on their mobile phone. Further details of a suitable notification system are described in detail in UK patent application number GB1919457.0, which is incorporated herein by reference.

The second mechanism may comprise a first component configured to hook onto a second component to prevent movement of the main housing with respect to the mounting bracket; and wherein the second mechanism may be configured such that manipulation by unhooking the first and second components enables movement of the main housing with respect to the mounting bracket. The unhooking of the first and second components may only be possible after partial or full removal of the further housing component. In some embodiments, engagement of the further housing component may not only prevent access to the second mechanism but may also serve to lock the second mechanism in an engaged position. For example, the further housing component may be located so as to lock the first and second components in a hooked configuration at least during insertion of the further housing component into engagement with the main housing. In other words, the presence of the further housing component in the main housing may block the first and/or second components such that it is not possible for the first and second components to be unhooked.

The first component may comprise a projection, the second component may comprise a ledge and at least one of the projection and the ledge may be chamfered to permit one of the first and second components to slide over another of the first and second components in a direction of engagement.

The first component may be provided on one of the main housing and the mounting bracket and the second component may be provided on the other of the main housing and the mounting bracket. For example, the first component may be provided on the main housing and the second component using may be provided on the mounting bracket, or vice versa.

The second mechanism may be configured to passively lock the main housing to the mounting bracket when installed thereon. For example, engagement of the main housing on the mounting bracket during an assembly process may automatically result in locking of the main housing to the mounting bracket (e.g. without specific operator intervention to lock the components together). This may be achieved, for example, when the main housing is slid into engagement with the mounting bracket such that the second mechanism snap-fits into a locked arrangement.

The second mechanism may be configured such that force of gravity at least assists to passively lock the main housing to the mounting bracket. The gravity may assist the passive locking by virtue of being the same direction (i.e. downwards) that the main housing needs to move to lock to the mounting bracket.

The second mechanism may be configured to provide one or more of: an audible indication; and a visible indication upon locking the main housing to the mounting bracket. For example, if the second mechanism is configured for a snap-fit this may produce an audible ‘click’ when engaged. In other embodiments, a mechanical flag or LED indicator may be visible when the main housing is locked on the mounting bracket.

The second mechanism may be configured for manipulation to enable sliding movement of the main housing with respect to the mounting bracket, when the housing assembly is at least partially opened.

The second mechanism may be accessible at or towards a lower end of the main housing when mounted by the mounting bracket on a support, when the housing assembly is at least partially opened. In some embodiments, the second mechanism may be accessible by at least one finger of a person’s hand, from a lower end of the main housing.

The security device may comprise at least one sensor arrangement that has a field of view for sensing electromagnetic waves from an environment.

The field of view of the at least one sensor arrangement may be directed more towards one end of the security device than another opposite end of the security device and wherein the second mechanism may be accessible at or towards said one end, when the housing assembly is opened.

The at least one sensor arrangement may comprise at least one of:
a sensor arrangement for a motion detector; and
a sensor arrangement for a camera.

The at least one sensor arrangement may comprise one or more of: a radar sensor arrangement, a sonar sensor arrangement and a lidar sensor arrangement.

The security device may comprise a passive infrared motion detector having a lens mounted at or towards a lower end of the main housing when mounted by the mounting bracket on a support.

In a second aspect of the present invention, there is provided a method of retaining a main housing of a security device on a mounting bracket when inserting a further housing component into engagement with the main housing, when mounted by the mounting bracket on a support, the method comprising:
exerting a force on the main housing to move the main housing with respect to the mounting bracket during insertion of the further housing component; and
preventing such movement by engagement of a mechanism serving to retain the main housing on the mounting bracket.

If a component (e.g. the power supply housing) is removed (e.g. for battery replacement) and subsequently reinserted into a main housing of a security device whilst mounted on a mounting bracket, wherein insertion of the component exerts an upward force on the main housing that would encourage sliding movement of the main housing relative to the mounting bracket, potentially resulting in complete disengagement if the main housing is not held in position, this aspect of the present invention may prevent such movement.

Thus, in embodiments of the second aspect of the invention the main housing will not inadvertently be moved or disengaged from the mounting bracket on insertion of a further component, such as a power supply housing, due to engagement of the mechanism preventing such movement.

The step of preventing such movement may comprise sliding the main housing into a locking engagement with the mounting bracket.

The insertion of the further housing component may prevent manipulation of the mechanism to move the main housing with respect to the mounting bracket.

The further housing component may comprise a power supply housing for holding at least one power cell for supplying power to the security device.

In a third aspect of the present invention, there is provided a method of removing a main housing from a security device, the security device comprising a housing assembly comprising a mounting bracket and the main housing detachably mountable to the mounting bracket, the method comprising:
using a first mechanism to at least partially open the housing assembly;
accessing a second mechanism when the housing assembly is at least partially open;
manipulating the second mechanism to unlock the main housing with respect to the mounting bracket; and
moving the main housing with respect to the mounting bracket.

The security device may comprise a further housing component and the step of using the first mechanism to at least partially open the housing assembly may comprise using the first mechanism to move (e.g. slide) the further housing component with respect to the main housing to thereby at least partially open the housing assembly.

The further housing component may comprise a power supply housing for holding at least one power cell for supplying power to the security device.

In accordance with a fourth aspect of the invention there is provided a security device comprising:
a housing assembly comprising a mounting bracket, a main housing detachably mountable to the mounting bracket and a further housing component engagable with the main housing;
wherein a mechanism is provided such that manipulation of the mechanism allows the main housing to be slidably moveable with respect to the mounting bracket in a direction substantially aligned with a direction of insertion of the further housing component into engagement with the main housing; and
wherein said slidable movement is prevented by said mechanism at least during insertion of the further housing component into engagement with the main housing.

The mechanism, which may be the same as the second mechanism described above, may comprise a first component configured to hook onto a second component. As such, the mechanism may be considered to be in the form of a latch or a catch for providing a fixing or locking engagement. The mechanism may be biased to an engaged (e.g. hooked) configuration.

The unhooking of the first component and the second component may be prevented by presence of the further housing component, at least during insertion of the further housing component into engagement with the main housing. For example, the further housing component may be located to as to lock the first and second components in a hooked configuration at least during insertion of the further housing component into engagement with the main housing. In other words, the presence of the further housing component in the main housing may block the first and/or second components such that it is not possible for the first and second components to be unhooked. Accordingly, the further housing component may not only prevent access to the mechanism but may also serve to lock the mechanism in an engaged position.

As used herein, except where the context requires otherwise, the terms “comprises”, “includes”, “has”, and grammatical variants of these terms, are not intended to be exhaustive. They are intended to allow for the possibility of further additives, components, integers or steps.

Features in one aspect may be applied as features in any other aspect, in any appropriate combination. For example, method features may be provided as device features or vice versa.

### BRIEF DESCRIPTION OF THE DRAWINGS

Embodiments will now be described by way of example only, and with reference to the accompanying drawings, of which:

FIG. 1 is a front perspective view of a security device according to a first embodiment of the invention;

FIG. 2 is a rear perspective view of the security device of FIG. 1;

FIG. 3 is an end perspective view of the security device of FIG. 1 with a power supply housing installed;

FIG. 4A is a side view of the security device of FIG. 1 with the power supply housing installed;

FIG. 4B is a cross-sectional view of the security device of FIG. 4A;

FIG. 4C shows a part middle front to rear cross-sectional view of the security device of FIG. 4A with the power supply housing in the installed configuration but the batteries removed;

FIG. 5A is a side view of the security device of FIG. 1 with the power supply housing partially installed;

FIG. 5B is a cross-sectional view of the security device of FIG. 5A;

FIG. 5C is an enlarged view of a central portion of FIG. 5B showing the engagement of the second mechanism;

FIG. 6 shows a cross-sectional view similar to that of FIG. 5B but with the power supply housing completely removed;

FIG. 7 shows a side view of a main housing component of the security device of FIG. 1, including an engagement part of the second mechanism;

FIG. 8 shows a rear perspective view of the main housing component of FIG. 8;

FIG. 9 shows a front perspective view of a mounting bracket of the security device of FIG. 1, including an engagement part of the second mechanism;

FIG. 10 is a schematic diagram showing a power supply, electric trigger circuit, processing circuitry and transmitter of the security device of FIG. 1;

FIG. 11 illustrates a method of retaining a main housing of a security device on a mounting bracket when inserting a further housing component into engagement with the main housing, in accordance with embodiments of the invention; and

FIG. 12 illustrates a method of removing a main housing from a security device in accordance with embodiments of the invention.

### DETAILED DESCRIPTION OF THE EMBODIMENTS

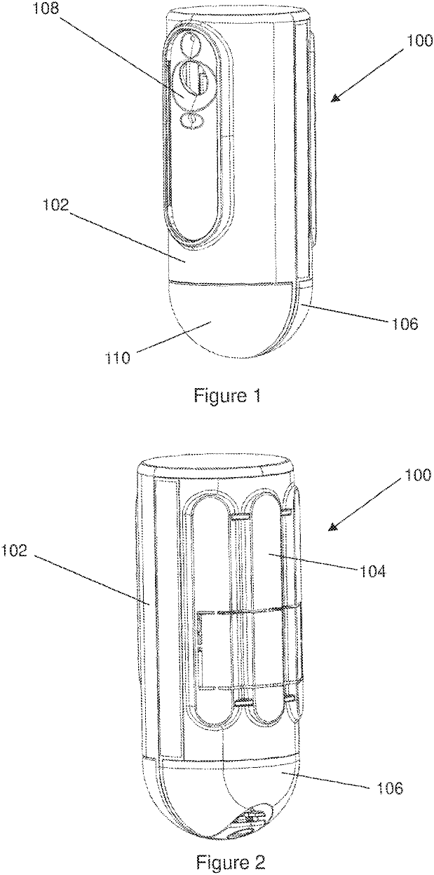

FIGS. 1 and 2 show, respectively, front and rear views of a security device 100 according to a first embodiment of the invention. The security device 100 comprises a housing assembly comprising a main housing 102 and a mounting bracket 104 for mounting the security device 100 to a wall or other support. As will be described in more detail below, the main housing 102 is detachably mountable to the mounting bracket 104. The housing assembly also comprises a further housing component in the form of a power supply housing 106. Although, in other embodiments, the further component may form another part of the housing assembly.

The main housing 102 incorporates processing circuitry (not shown) and a sensor arrangement 108. The sensor arrangement 108 may comprise one or more sensors and the/each sensor may be internal to the security device 100 and may receive information via optics (e.g. one or more lenses) on the housing. An example of such a sensor is an image sensor. In some embodiments, the sensor arrangement 108 may additionally or alternatively comprise a motion sensor (e.g. a PIR sensor) which may be provided beneath a bottom lens 110.

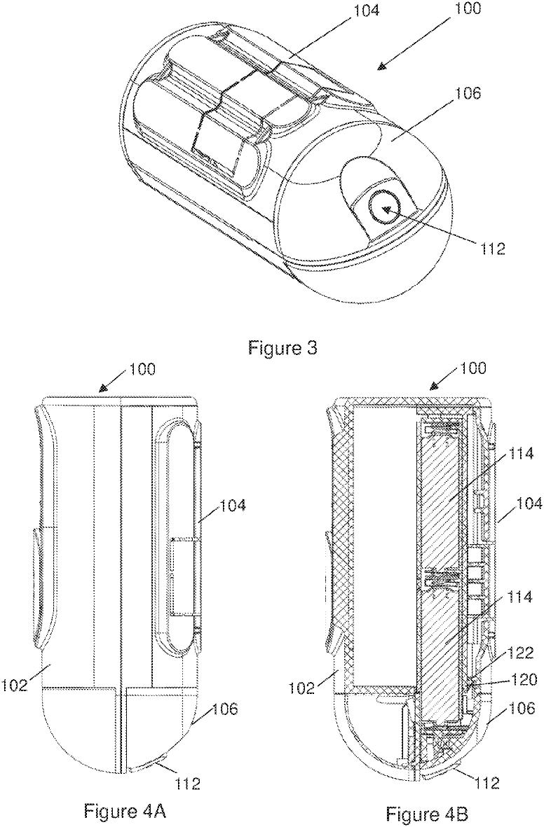

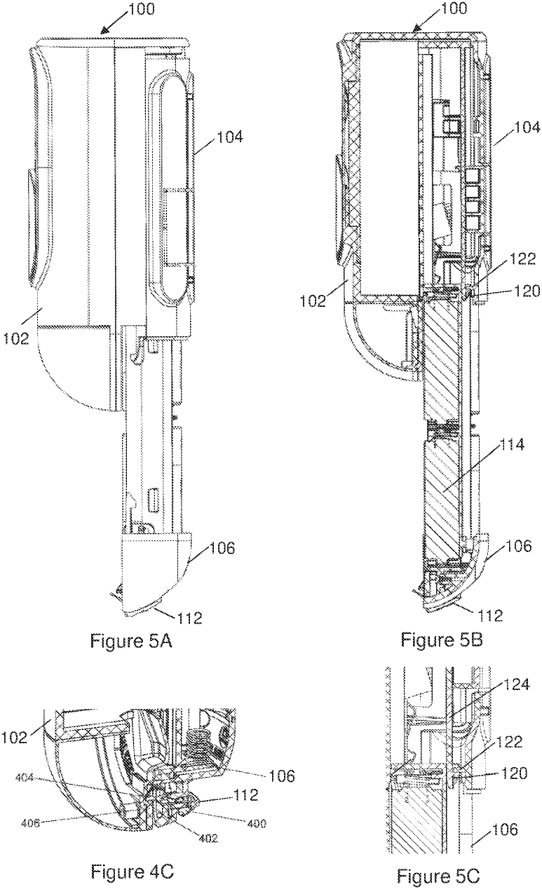

As shown in FIGS. 3, 4A, 4B and 4C, a lower end of the security device 100 has a first mechanism in the form of an actuator 112, which can be pulled to open the housing assembly from the closed configuration shown. In the present embodiment, the actuator 112 is in the form of a lever 400 which when pivoted around a pin 402 releases a catch 404 from a ledge 406 on the main housing 102 thereby allowing the power supply housing 106 to fall, or be pulled, from its fully inserted or fully engaged position so as to place the main housing in an at least partially open configuration as shown in FIGS. 5A and 5B.

Returning to FIG. 4B, an interior of the power supply housing 106 is configured for receipt of one or more power cells 114. In the embodiment shown, four batteries may be inserted into a front side of the power supply housing 106 (two of which are shown in FIG. 4B) and two further batteries may be inserted into a rear side of the power supply housing 106 for supply of power to the processing circuitry and sensor arrangement 108 in the main housing 102. In other embodiments, other numbers of batteries or other power cells may be employed.

As shown in FIG. 4B, in the closed configuration, a second mechanism comprising a projection 120 on the interior of the main housing 102 and a ledge 122 on the interior of the mounting bracket 102 are engaged to prevent upward movement and/or detachment of the main housing 102 with respect to the mounting bracket 104. Notably, the second mechanism is inaccessible in the closed configuration to prevent actuation (e.g. by manipulating the projection 120 to be clear of the ledge 122) and thereby ensure that the main housing 102 is not inadvertently dislodged from the mounting bracket 104. The manipulation of the projection 120 may be by a person’s finger accessing the projection 120 from below.

Notably, the projection 120 is tapered or chamfered to facilitate movement past the ledge 122 when the main housing 102 is slid into engagement with the mounting bracket 104. This results in a snap-fit arrangement locking the main housing 102 to the mounting bracket 104. The movement into the snap-fit may be audible. In other embodiments, the ledge 122 may additionally or alternatively, be tapered or chamfered.

As shown in FIGS. 5A, 5B and 5C, the power supply housing 106 is slid downwards to release it from the main housing 102 and slid upwards for insertion into the main housing 102. As best shown in FIG. 5C, the power supply housing 106 is configured to slide against and abut a leg 124 on which the projection 120 is provided from initial insertion to complete insertion of the power supply housing 106 within the main housing 102. This ensures that the projection 120 cannot be moved passed the ledge 122 to allow the main housing to be moved upwardly and disengaged with respect to the mounting bracket 104, when the power supply housing 106 is inserted.

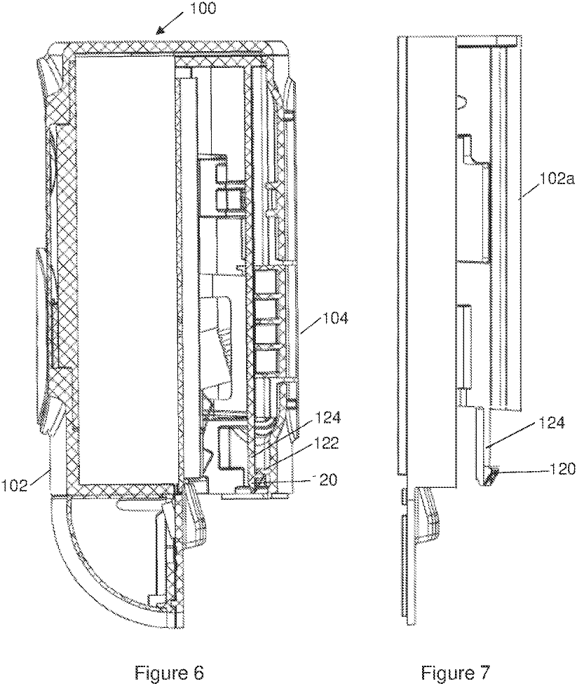

FIG. 6 shows a view similar to that of FIG. 4B but with the power supply housing 104 completely removed from the main housing 102 to place the housing assembly in a fully open configuration. As such it will be noted that the second mechanism is accessible to be manipulated or actuated to enable movement (which may or may not result in detachment) of the main housing 102 with respect to the mounting bracket 104. More specifically, an operator may manipulate the projection 120 by forcing the leg 124 to bend or pivot so that the projection 120 unhooks from the ledge 122 and allows the main housing 102 to slide upwardly out of engagement with the mounting bracket 104.

In other embodiments, it may not be necessary to completely remove the power supply housing 104 from the main housing 102 in order to access the projection 120. In such embodiments, the projection 120 may be accessible when the device is in a partially open state, for example, with the power supply housing 104 only partially removed from the main housing 102. In this case, a wall portion would not exist to block access to the second mechanism and the projection 120 may be manipulated by the power supply housing 104 having a modified shape such that there is a gap between the power supply housing 104 and the projection 120. This would allow the projection 120 to be manipulated even if the power supply housing 104 was only partially removed (i.e. with the housing assembly in a partially open configuration).

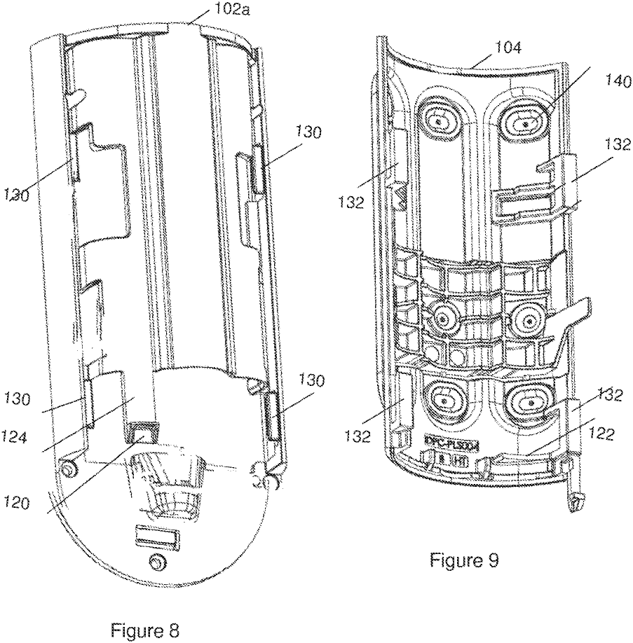

FIG. 7 shows a component 102a of the main housing 102. The component 102a is the portion of the main housing 102 that engages with the mounting bracket 104 during use. This clearly shows the projection 120 at the end of the leg 124. FIG. 8 is a rear perspective view of the component 102a which shows a width of the leg 124 and projection 120. In addition, FIG. 8 shows two upper rails 130 and two lower rails 130 attached along the outer edges and extending inwardly from the sides of the component 102a. These rails 130 are configured to be aligned above and then slid downwards into grooves formed by U-shaped projections 132 on the sides of the mounting bracket 104 to allow sliding engagement of the main housing 102 with the mounting bracket 104.

An interior of the mounting bracket 104 is shown in FIG. 9. In use, the mounting bracket 104 is affixed to a wall or other support by screws (not shown). The screws may be self-tapping, and driven through designated locations 140 on the mounting bracket 104 to affix the mounting bracket 104 to the wall. The main housing 102, including the component 102a but not the power supply housing 106 is then slidably engaged on the mounting bracket 104 by arranging the upper and lower rails 130 over the grooves formed by the U-shaped projections 132 on the sides of the mounting bracket 104 and then sliding the main housing 102 downwardly to engage the rails 130 in the grooves before the projection 120 passes over and engages with the ledge 122 to lock the components in position.

At this stage, the security device 100 is in the fully open configuration shown in FIG. 6 and the second mechanism is accessible (e.g. by a person’s finger) to move the main housing 102 with respect to the mounting bracket 104 and to ultimately disengage it therefrom. However, insertion of the power supply housing 106 into the main housing 102, as shown in FIGS. 5A and 5B will prevent the second mechanism from being accessed and actuated and will result in the second mechanism being inaccessible when the power supply housing 106 is inserted. In this case, the second mechanism is inaccessible during the entire insertion process (i.e. even when the power supply housing 106 is only partially inserted) because parts of the components prevent access, but in other embodiments the second component may be inaccessible only at or towards an end of the insertion process (i.e. when the power supply housing 106 is fully inserted). In addition, the act of inserting the power supply housing 106 into the main housing 102 will generate an upwards force on the main housing 102 which would, in the absence of the projection 120 being locked onto the ledge 122, result in the main housing 102 disengaging from the mounting bracket 104 unless held firmly in place. However, the provision of the second mechanism prevents such upward movement of the main housing 102 with respect to the mounting bracket 104 when the power supply housing is inserted 106. This is because the upwards force is transferred to the projection 120 and the movement of which catches against the underside of the ledge 122 thereby preventing movement leading to detachment of the main housing 102 with respect to the mounting bracket 104.

It should be noted that the concept of accessibility (e.g. on partial insertion of the power supply housing 106) may be dependent on whether there is a part or wall in the way, but the concept of being able to manipulate or actuate the second mechanism may require complete removal of a component, even if there is no part or wall in the way.

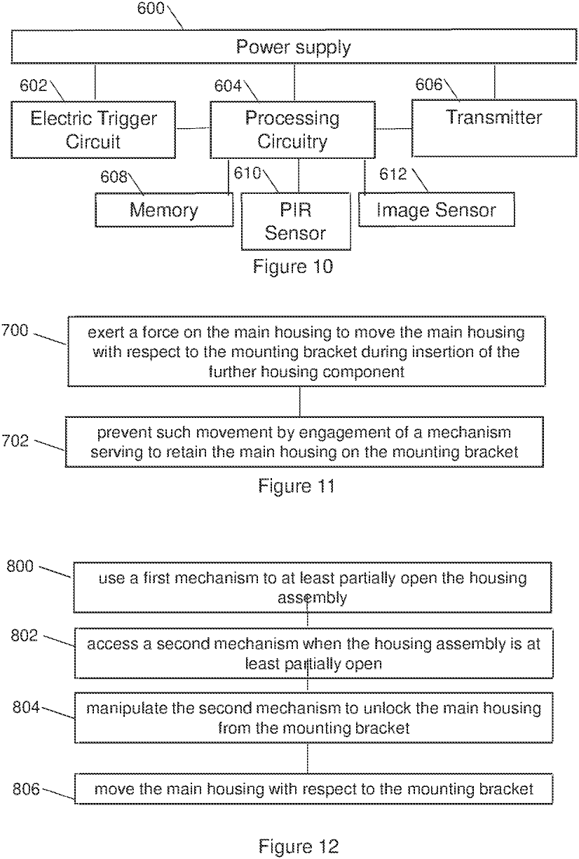

FIG. 10 is a schematic diagram showing a power supply 600 connected to an electric trigger circuit 602, processing circuitry 604 and a transmitter 606 of the security device 100 of FIG. 1. Note, these electrical components are not shown in the above figures for clarity. However, it will be understood that the power supply 600 corresponds to power supplied by the batteries provided in the power supply housing 106.

During normal operation of the security device 100, the power supply housing 106 is installed in the main housing 102 and the power supply 600 is connected to the processing circuitry 604 to control operation of the security device 100. Thus, the processing circuitry 604 controls the sensor arrangement 108 to monitor an environment. In the embodiment shown in FIG. 10, the sensor arrangement 108 comprises a PIR sensor 610 and an image sensor 612. In some embodiments, a motion detected based on the PIR sensor may be used by the security device 100, at least under some conditions, to trigger capturing of one or more images using the image sensor 612. Although not shown in FIG. 10, the PIR sensor 610 and the image sensor 612 are also connected to the power supply 600.

UK patent application number GB1919457.0 describes ways in which is it possible to detect, and transmit a notification of, removal or at least partial removal of a power supply from a security device and which may be employed in embodiments of the present invention. In other embodiments, the removal or partial removal of the power supply housing 106 may be detected by a sensor (e.g. a mechanical switch; optical sensor, etc.) on the main housing 102 which triggers a notification, with the main housing 102 having sufficient capacitance to maintain operation of the processing circuitry 604 for long enough to instruct the transmitter 606 to send a message to a control panel to indicate that the power supply housing 106 is being removed.

Optionally, an authorization check may be performed and action may then be taken at the control panel to check whether the removal of the power supply housing 106 is authorised or not.

As also shown in FIG. 10, a memory 608 is provided in communication with the processing circuitry 604. The memory 608 may comprise a non-transient computer readable medium comprising instructions operable by the processing circuitry 604.

The processing circuitry 604 may comprise one or more processing chips and/or components. For example, the processing circuitry may comprise: control circuitry; and/or processor circuitry; and/or at least one application specific integrated circuit (ASIC); and/or at least one field programmable gate array (FPGA); and/or single or multi-processor architectures; and/or sequential/parallel architectures; and/or at least one programmable logic controllers (PLCs); and/or at least one microprocessor; and/or at least one microcontroller; and/or a central processing unit (CPU); and/or a graphics processing unit (GPU).

A transceiver that includes the transmitter 606 may be distinct from the processing circuitry 604, but in some embodiments at least part of the processing aspects of the transceiver may have hardware in common with a processor component of the processing circuitry 604.

The memory 608 may be separate from the processing circuitry 604 and/or partly or wholly integrated onto a common chip(s) with the processing circuitry 604. The memory 608 may store code that, when read by the processing circuitry 604, causes performance of a method of operation. For example, the memory may comprise: volatile memory, for example, one or more dynamic random access (DRAM) modules and/or static random access memory (SRAM) modules; and/or non-volatile memory, for example, one or more read only memory (ROM) modules, which for example may comprise a Flash memory and/or other electrically erasable programmable read-only memory (EEPROM) device. The code may for example be software, firmware, or hardware description language (HDL) or may be any combination of these or any other form of code for one or more processors that is known by a person skilled in the art.

In other embodiments, the memory component of the device may instead or at least in part be provided by a memory device(s) that may in some embodiments be separate or removable from the device. Such devices may comprise magnetic storage devices (e.g., hard disk, floppy disk, magnetic strips), optical disks (e.g., compact disk (CD), digital versatile disk (DVD)), smart cards, and removable flash memory devices (e.g., card, stick, key drive). Furthermore, the memory components may be distributed. For example a distributed server may store code which may be downloaded to the device for execution by the processing circuitry described herein, to perform any method that is executable by the processing circuitry. In some embodiments the downloaded code may be stored on local memory of the device before execution by the processing circuitry.

FIG. 11 illustrates generally a method of retaining a main housing 102 of a security device 100 on a mounting bracket 104 when inserting a further housing component 106 into engagement with the main housing 102, when mounted by a mounting bracket 104 on a support in accordance with embodiments of the invention. Thus, there is a step 700 of exerting a force on the main housing 102 to move the main housing 102 with respect to the mounting bracket 104 during insertion of the further housing component 106. There is also a step 702 of preventing such movement by engagement of a mechanism serving to retain the main housing 102 on the mounting bracket 104. As described above, the insertion of the further housing component 106 may prevent manipulation or actuation of the mechanism (i.e. movement of the projection 120) to move and potentially release the main housing 102 with respect to the mounting bracket 104. The step of preventing such movement may comprise sliding the main housing 102 into a locking engagement with the mounting bracket 104. As described previously, the further housing component 106 may comprise a power supply housing 106 for holding at least one power cell for supplying power to the security device 100.

FIG. 12 illustrates generally a method of removing a main housing 102 from a security device 100, the security device 100 comprising a housing assembly comprising a mounting bracket 104 and the main housing 102 detachably mountable to the mounting bracket 104 in accordance with embodiments of the invention. Thus, there is a step 800 of using a first mechanism 112 to at least partially open the housing assembly; a step 802 of accessing a second mechanism 120 when the housing assembly is at least partially open; a step 804 of manipulating the second mechanism 120 to unlock the main housing 102 from the mounting bracket 104; and a step 806 of moving detaching the main housing 102 with respect to the mounting bracket 104. As above, the security device 100 may comprise a further housing component in the form of a power supply housing 106, and the step of using the first mechanism 112 to at least partially open the housing assembly may comprise using the first mechanism 112 to move the further housing component with respect to the main housing 102 to thereby at least partially open the housing assembly.

Thus, certain embodiments of the invention provide a security device configured to retain a main housing on a mounting bracket until selectively moved, said movement potentially leading to release of the main housing from the mounting bracket. The main housing will therefore not inadvertently be moved or disengaged from the mounting bracket on insertion of a further component such as a power supply housing. In addition, the selective movement of the main housing can only be achieved after the device is placed in an at least partially open configuration (i.e. after full or partial removal of a component such as a power supply housing) due to the inaccessibility of the second mechanism when the device is in the closed configuration. Accordingly, it is more difficult for an untrained person to remove the main housing from the mounting bracket.

Whilst the foregoing description has described exemplary embodiments, it will be understood by those skilled in the art that many variations of the embodiments can be made within the scope of the present invention as defined by the claims. Moreover, features of one or more embodiments may be mixed and matched with features of one or more other embodiments.

1. A security device comprising:
a housing assembly comprising a mounting bracket and a main housing detachably mountable to the mounting bracket;
wherein the housing assembly has a closed configuration that can be at least partially opened using a first mechanism;
wherein, when the housing assembly is at least partially opened, a second mechanism is accessible to be manipulated to enable movement of the main housing with respect to the mounting bracket;
wherein in the closed configuration the second mechanism prevents movement of the main housing with respect to the mounting bracket and is inaccessible to thereby prevent said manipulation;
wherein the housing assembly comprises a further housing component and wherein, in the closed configuration, the further housing component is in engagement with the main housing so as to make the second mechanism inaccessible; and
wherein the further housing component comprises a power supply housing for holding at least one power cell for supplying power to the security device; and
wherein removal of the power supply housing from the main housing enables access to the second mechanism.

2. The security device of claim 1, wherein the first mechanism is configured to move the further housing component with respect to the main housing to at least partially open the housing assembly and thereby make the second mechanism accessible.

3. The security device of claim 1, wherein the second mechanism is configured such that movement of the main housing with respect to the mounting bracket is prevented at least during insertion of the further housing component into engagement with the main housing.

4. The security device of claim 3, wherein the main housing is slidably moveable with respect to the mounting bracket in a direction substantially aligned with a direction of insertion of the further housing component, when the second mechanism has been manipulated, and is restrained against said slidable movement by operation of the second mechanism at least during insertion of the further housing component into engagement with the main housing.

5-24. (canceled)

25. A security device comprising:
a housing assembly comprising a mounting bracket, a main housing detachably mountable to the mounting bracket and a further housing component engagable with the main housing;
wherein a mechanism is provided such that manipulation of the mechanism allows the main housing to be slidably moveable with respect to the mounting bracket in a direction substantially aligned with a direction of insertion of the further housing component into engagement with the main housing; and
wherein said slidable movement is prevented by said mechanism at least during insertion of the further housing component into engagement with the main housing.

26. The security device of claim 25 wherein the mechanism comprises a first component configured to hook onto a second component.

27. The security device of claim 26 wherein unhooking of the first component and the second component is prevented by presence of the further housing component, at least during insertion of the further housing component into engagement with the main housing.

28. The security device of claim 27 wherein the further housing component is locatable so as to lock the first and second components in a hooked configuration at least during insertion of the further housing component into engagement with the main housing.

29. The security device of claim 27 wherein the presence of the further housing component in the main housing blocks the first and/or second components such that it is not possible for the first and second components to be unhooked.

30. The security device of claim 25 wherein the further housing component prevents access to the mechanism.

31. The security device of claim 25 wherein the further housing component serves to lock the mechanism in an engaged position.

32. The security device of claim 25 wherein the mechanism is biased to an engaged configuration.

33. The security device of claim 25 wherein the further housing component comprises a power supply housing for holding at least one power cell for supplying power to the security device.

34. The security device of claim 33, wherein removal of the power supply housing to enable access to the mechanism in order to remove the main housing, triggers a processor to generate a notification to indicate at least one of (i) that the housing assembly has been at least partially opened, and (ii) that the power supply housing has been accessed.

35. The security device of claim 26, wherein the first component comprises a projection, the second component comprises a ledge and at least one of the projection and the ledge is chamfered to permit one of the first and second components to slide over another of the first and second components in a direction of engagement.

36. The security device of claim 26, wherein the first component is provided on the main housing and the second component is provided on the mounting bracket.

37. The security device of claim 25, wherein the mechanism is configured to passively lock the main housing to the mounting bracket when installed thereon.

38. The security device of claim 37, wherein the mechanism is configured such that force of gravity at least assists to passively lock the main housing to the mounting bracket.

39. The security device of claim 25, wherein the mechanism is configured to provide one or more of: an audible indication; and a visible indication upon locking the main housing to the mounting bracket.

40. The security device of claim 25, wherein the second mechanism is accessible at or towards a lower end of the main housing when mounted by the mounting bracket on a support, when the housing assembly is at least partially opened.
